(19) United States
(12) Patent Application Publication
(10) Pub. No.: US 2025/0113611 A1
(43) Pub. Date: Apr. 3, 2025

(54) DISPLAY SUBSTRATE AND DISPLAY DEVICE

(71) Applicants: HEFEI BOE OPTOELECTRONICS TECHNOLOGY CO., LTD., Hefei (CN); BOE TECHNOLOGY GROUP CO., LTD., Beijing (CN)

(72) Inventors: Ji Li, Beijing (CN); Zhengwei Zhu, Beijing (CN); Xiaojie Zhang, Beijing (CN); Cheng Li, Beijing (CN); Xiaofeng Yin, Beijing (CN)

(21) Appl. No.: 18/294,529

(22) PCT Filed: Dec. 26, 2022
(86) PCT No.: PCT/CN2022/141833

§ 371 Date: Feb. 1, 2024

(51) Int. Cl. H10D 86/40

(52) U.S. Cl. CPC H10D 86/441

(57) ABSTRACT

A display substrate includes: a base substrate; and a driving structure layer on a side of the base substrate. The display substrate includes a display region and a non-display region. The driving structure layer includes: an electrode layer including at least one first electrode and at least one second electrode adjacent to each other in the non-display region, wherein a potential of the first electrode is lower than that of the second electrode; and a conductor layer, where the conductor layer and the electrode layer are in different layers. The conductor layer includes a first conductor portion electrically connected to the first electrode and a second conductor portion electrically connected to the second electrode. An area of an orthographic projection of the first conductor portion on the base substrate is greater than that of the second conductor portion on the base substrate.

### CROSS REFERENCE TO RELATED APPLICATION(S)

This is a Section 371 National Stage Application of International Application No. PCT/CN2022/141833, filed on Dec. 26, 2022, entitled “DISPLAY SUBSTRATE AND DISPLAY DEVICE,” which is incorporated herein by reference in its entirety.

### TECHNICAL FIELD

The present disclosure relates to a field of display technology, and in particular, to a display substrate and a display device.

### BACKGROUND

With a development of display technology, displays are showing a trend of high integration and low cost. There are increasingly high requirements for a narrow bezel of screen. For TFT-LCD (Thin Film Transistor Liquid Crystal Display), with a use of GOA (Gate On Array) technology, a gate driving circuit may be integrated on an array substrate of a display panel, so that a separate gate driving integrated circuit portion may be omitted, material costs and manufacturing costs of a display device may be reduced, and a bezel design of panel may be reduced, thereby meeting the requirements of narrow bezel.

### SUMMARY

In order to solve the above problems, embodiments of the present disclosure provide a display substrate and a display device.

In an aspect, a display substrate is provided, including but not limited to: a base substrate; and a driving structure layer on a side of the base substrate, where the display substrate includes a display region and a non-display region, the driving structure layer includes: an electrode layer including at least one first electrode and at least one second electrode adjacent to each other in the non-display region, and a potential of the first electrode is lower than a potential of the second electrode; and a conductor layer, where the conductor layer and the electrode layer are in different layers, the conductor layer includes a first conductor portion electrically connected to the first electrode and a second conductor portion electrically connected to the second electrode, and an area of an orthographic projection of the first conductor portion on the base substrate is greater than an area of an orthographic projection of the second conductor portion on the base substrate.

In some exemplary embodiments of the present disclosure, the first electrode includes a first conductive portion and a second conductive portion, the first conductive portion and the second conductive portion are in different layers, and the first conductive portion and the second conductive portion are electrically connected through the first conductor portion; the second electrode includes a third conductive portion and a fourth conductive portion, the third conductive portion and the fourth conductive portion are in different layers, and the third conductive portion and the fourth conductive portion are electrically connected through the second conductor portion; and the first conductive portion and the third conductive portion are in a same layer, and the second conductive portion and the fourth conductive portion are in a same layer.

In some exemplary embodiments of the present disclosure, the electrode layer further includes a third electrode, and the third electrode is between the first electrode and the second electrode, and the third electrode is insulated from the second conductor portion, and a potential of the third electrode is lower than the potential of the second electrode.

In some exemplary embodiments of the present disclosure, the third electrode is in a same layer as the first conductive portion or the second conductive portion.

In some exemplary embodiments of the present disclosure, the third electrode is electrically connected to the first electrode, and the potential of the third electrode is the same as the potential of the first electrode.

In some exemplary embodiments of the present disclosure, an electric field intensity between the third electrode and the second conductor portion is greater than an electric field intensity between the first conductor portion and the second conductor portion.

In some exemplary embodiments of the present disclosure, a distance between the third electrode and the second conductor portion is less than a distance between the first conductor portion and the second conductor portion.

In some exemplary embodiments of the present disclosure, the electrode layer includes a plurality of first electrodes electrically connected through the third electrode.

In some exemplary embodiments of the present disclosure, the first electrode includes a first non-redundant electrode and a first redundant electrode; and the first conductor portion includes a first non-redundant conductor portion electrically connected to the first non-redundant electrode and a first redundant conductor portion electrically connected to the first redundant electrode.

In some exemplary embodiments of the present disclosure, the first redundant electrode is between the first non-redundant electrode and the second electrode.

In some exemplary embodiments of the present disclosure, a potential of the first redundant electrode is the same as a potential of the first non-redundant electrode.

In some exemplary embodiments of the present disclosure, the first redundant electrode is electrically connected to the first non-redundant electrode.

In some exemplary embodiments of the present disclosure, a first conductive portion of the first redundant electrode is connected to a first conductive portion of the first non-redundant electrode; and/or a second conductive portion of the first redundant electrode is connected to a second conductive portion of the first non-redundant electrode.

In some exemplary embodiments of the present disclosure, the first conductor portion includes a first non-redundant conductor portion electrically connected to the first non-redundant electrode and a first redundant conductor portion electrically connected to the first redundant electrode.

In some exemplary embodiments of the present disclosure, a distance between the first redundant conductor portion and the second conductor portion is greater than a distance between the first redundant electrode and the second conductor portion.

In some exemplary embodiments of the present disclosure, an electric field intensity between the first redundant conductor portion and the second conductor portion is less than an electric field intensity between the first redundant electrode and the second conductor portion.

In some exemplary embodiments of the present disclosure, an orthographic projection of the first conductor portion on the base substrate overlaps with an orthographic projection of the first electrode on the base substrate to form a first overlapping region; and/or an orthographic projection of the second conductor portion on the base substrate overlaps with an orthographic projection of the second electrode on the base substrate to form a second overlapping region.

In some exemplary embodiments of the present disclosure, the first conductor portion is connected to the first electrode through a first via hole, and an orthographic projection of the first via hole on the base substrate is located in the first overlapping region; and/or the second conductor portion is connected to the second electrode through a second via hole, and an orthographic projection of the second via hole on the base substrate is located in the second overlapping region.

In some exemplary embodiments of the present disclosure, the first conductor portion and the second conductor portion include a metal oxide or a metal.

In some exemplary embodiments of the present disclosure, the electrode layer further includes at least one fourth electrode and at least one fifth electrode adjacent to each other in the non-display region, where a potential difference between the fourth electrode and the fifth electrode is less than a potential difference between the first electrode and the second electrode, and a distance between the fourth electrode and the fifth electrode is less than a distance between the first electrode and the second electrode.

In another aspect of the present disclosure, a display device is provided, including the display substrate as described above.

### BRIEF DESCRIPTION OF THE DRAWINGS

With following descriptions of the present disclosure with reference to the accompanying drawings, other objectives and advantages of the present disclosure may be obvious and the present disclosure may be understood comprehensively, in the drawings:

FIG. 1A shows a schematic plan view of a display substrate according to embodiments of the present disclosure;

FIG. 1B shows a schematic cross-sectional view of a display substrate according to embodiments of the present disclosure;

FIG. 2 shows an equivalent circuit diagram of a driving circuit of a display substrate according to embodiments of the present disclosure;

FIG. 3A shows a schematic structural diagram of a driving circuit of a display substrate according to embodiments of the present disclosure;

FIG. 3B shows a partially enlarged view of region X in FIG. 3A;

FIG. 3C shows a schematic structural diagram of a gate layer in FIG. 3B;

FIG. 3D shows a schematic structural diagram of a source/drain layer in FIG. 3B;

FIG. 3E shows a schematic structural diagram of a conductive layer in FIG. 3B;

FIG. 3F shows a timing diagram of a second control signal terminal and nodes in FIG. 3A;

FIG. 4A shows a schematic structural diagram of a driving structure layer of a display substrate according to an embodiment of the present disclosure;

FIG. 4B shows a schematic structural diagram of a driving structure layer of a display substrate according to another embodiment of the present disclosure;

FIG. 4C shows a schematic structural diagram of a driving structure layer of a display substrate according to still another embodiment of the present disclosure;

FIG. 4D shows a schematic cross-sectional structural diagram of a driving structure layer taken along line A-A in FIG. 4C;

FIG. 4E shows a schematic cross-sectional structural diagram of a driving structure layer taken along line B-B in FIG. 4C;

FIG. 5A shows a schematic structural diagram of a driving circuit of a display substrate according to another embodiment of the present disclosure;

FIG. 5B shows a schematic structural diagram of a gate layer in FIG. 5A;

FIG. 5C shows a schematic structural diagram of an active layer in FIG. 5A;

FIG. 5D shows a schematic structural diagram of a source/drain layer in FIG. 5A;

FIG. 5E shows a schematic structural diagram of a conductive layer in FIG. 5A;

FIG. 6A shows a schematic structural diagram of a driving structure layer of a display substrate according to still another embodiment of the present disclosure;

FIG. 6B shows a schematic cross-sectional structural diagram of a driving structure layer taken along line C-C in FIG. 6A;

FIG. 6C shows a schematic cross-sectional structural diagram of a driving structure layer taken along line D-D in FIG. 6A;

FIG. 6D shows a schematic diagram of a distribution of electric field lines in FIG. 6B;

FIG. 6E shows a schematic diagram of a distribution of electric field lines in FIG. 6C;

FIG. 7A shows a schematic structural diagram of a driving structure layer of a display substrate according to yet another embodiment of the present disclosure;

FIG. 7B shows a schematic cross-sectional structural diagram of a driving structure layer taken along line E-E in FIG. 7A;

FIG. 7C shows a schematic diagram of a distribution of electric field lines in FIG. 7B;

FIG. 8 shows a comparison diagram between a corrosion effect on an existing driving structure layer and a corrosion effect on a driving structure layer of a display substrate according to embodiments of the present disclosure.

It should be noted that for the sake of clarity, in the accompanying drawings used to describe embodiments of the present disclosure, sizes of layers, structures or regions may be enlarged or reduced, that is, those accompanying drawings are not drawn according to actual scale.

### DETAILED DESCRIPTION OF EMBODIMENTS

Technical solutions of the present disclosure will be further described in detail below through embodiments with reference to the accompanying drawings. In the specification, the same or similar reference numerals represent the same or similar components. The following descriptions of embodiments of the present disclosure with reference to the accompanying drawings are intended to explain a general inventive concept of the present disclosure, and should not be understood as a limitation to the present disclosure.

In addition, in the following detailed descriptions, for convenience of explanation, many specific details are set forth to provide comprehensive understanding of embodiments of the present disclosure. However, it is clear that one or more embodiments may also be implemented without these specific details.

It should be noted that although the terms “first”, “second”, and so on may be used herein to describe various components, members, elements, regions, layers and/or portions, these components, members, elements, regions, layers and/or portions should not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, may be used herein to describe a relationship between an element or feature and another element or feature as shown in the figures. It should be understood that the spatial relationship terms are intended to cover other different orientations of a device in use or operation in addition to the orientation described in the figures. For example, if a device in the figures is turned upside down, an element or feature described as “below” or “under” another element or feature will be oriented “above” or “on” the another element or feature.

It should be noted that the expressions “same layer” herein refer to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expressions “continuously extending”, “integral structure”, “overall structure” or similar expressions herein mean that a plurality of elements, components, structures and/or portions are located in the same layer and generally formed by the same patterning process during the manufacturing process, and that these elements, components, structures and/or portions are not separated or broken, but are formed as a continuously extending structure.

Herein, directional expressions “first direction” and “second direction” are used to describe different directions along a pixel region, e.g., a longitudinal direction and a lateral direction of the pixel region. It should be understood that such expressions are just exemplary descriptions and are not limitations to the present disclosure.

In related art, with a development of a display device technology, a narrow bezel technology is more and more widely used. By integrating a driving circuit of a display device on an array substrate of a display panel, a separate driving integrated circuit portion may be omitted, and a bezel of the panel may be reduced to meet requirements for a narrower bezel. However, with an increasingly smaller bezel of a screen, a distance between TFT transistors inside GOA also becomes increasingly smaller, and a distance between electrodes with different potentials decreases. During an operation of display device, there are some problems during a use of a display device designed with a narrow bezel. For example, in a case of a certain amount of water vapor in an operating environment, heat generated during the operation of the display device may promote the water vapor to penetrate into the display device. When the distance between the electrodes with different potentials is small, the incoming water vapor promotes an electrochemical corrosion between the electrodes with different potentials in the driving circuit, which may cause a corrosion of a low potential electrode, lead to a circuit disconnection, and finally result in a failure of display device and a short life of display substrate.

For example, a gate driving circuit of an existing display device may include a plurality of electrodes, and the electrodes may have different potentials. When the display substrate operates in an environment with certain humidity, water molecules in the environment may enter the electrodes with different potentials of the gate driving circuit from the outside. The water molecules may form electrolyte in a form of liquid between electrodes with different levels, and an electrochemical reaction may occur under the action of different levels.

For example, when indium tin oxide (ITO) is contained in a cathode electrode, the electrolytic reaction that occurs at the cathode is as follows: In₂O₃+3H₂O+6e→2 In+6OH—, and the electrolytic reaction that occurs at the anode is as follows: 4OH—→O₂+2H₂O+4e.

A film layer of indium tin oxide at the cathode has a fixed thickness. As a usage time increases, the film layer of indium tin oxide at the cathode may finally fail due to the electrochemical corrosion, and a service life of the display panel may be shortened.

In order to address the above problems, embodiments of the present disclosure provide a display substrate, including but not limited to: a base substrate; and a driving structure layer on a side of the base substrate. The display substrate includes a display region and a non-display region. The driving structure layer includes: an electrode layer, which includes at least one first electrode and at least one second electrode adjacent to each other in the non-display region, where a potential of the first electrode is lower than a potential of the second electrode; a conductor layer, where the conductor layer and the electrode layer are located in different layers, and the conductor layer includes a first conductor portion electrically connected to the first electrode and a second conductor portion electrically connected to the second electrode. An area of an orthographic projection of the first conductor portion on the base substrate is greater than an area of an orthographic projection of the second conductor portion on the base substrate.

According to embodiments of the present disclosure, with the design that the area of the orthographic projection of the first conductor portion connected to a low potential electrode on the base substrate is greater than the area of the orthographic projection of the second conductor portion connected to a high potential electrode on the base substrate, the problem of the display substrate failure caused by the electrochemical corrosion may be effectively mitigated, and the service life of the display substrate may be prolonged.

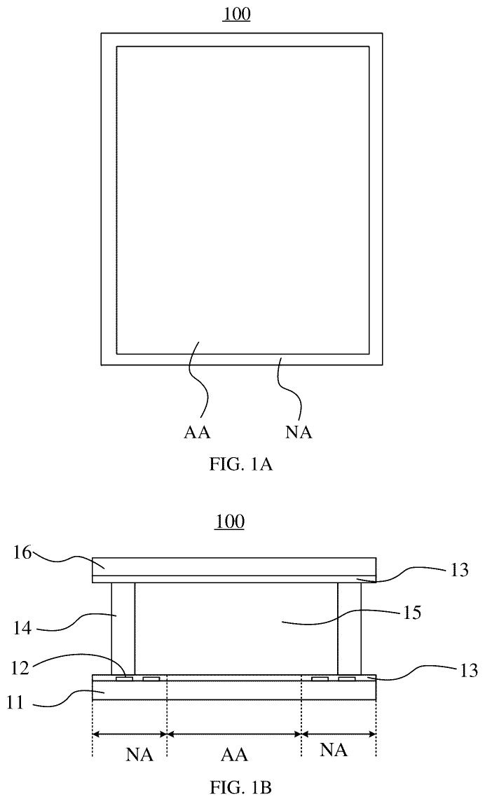

The display substrate of embodiments of the present disclosure will be described in detail below with reference to FIG. 1A to FIG. 7C.

FIG. 1A shows a schematic plan view of a display substrate according to embodiments of the present disclosure. FIG. 1B shows a schematic cross-sectional view of the display substrate according to embodiments of the present disclosure.

As shown in FIG. 1A, a display substrate 100 of embodiments of the present disclosure includes a display region AA and a non-display region NA (e.g., bezel region). The display region of the display substrate 100 includes a plurality of pixel units. A cross-sectional structure of the display substrate 100 is shown in FIG. 1B, which includes a base substrate 11, a driving structure layer 12, an alignment film 13, a sealant 14, a liquid crystal 15, and a color filter substrate 16.

The driving structure layer 12 is provided on a side of the base substrate 11, and includes the display region AA and the non-display region NA. The display region AA is used for display, and the non-display region NA is used to provide a bezel of the display substrate so as to achieve a fixation or other operations on the display substrate. The alignment film 13 is provided on a side of the driving structure layer 12 away from the base substrate. In such embodiments, the alignment film 13 includes two layers, namely a layer of alignment film 13 on the base substrate 11 and a layer of alignment film 13 on the color filter substrate 16. The liquid crystal 15 is provided between the two layers of alignment film 13. The sealant 14 is provided in the non-display region NA of the display substrate, and the liquid crystal 15 is isolated from the outside in the display region AA through the sealant 14, so as to prevent the liquid crystal 15 from coming into contact with the outside. The color filter substrate 16 is provided on an upper side of the alignment film 13 away from the base substrate 11, that is, the color filter substrate 16 is provided on a side of the alignment film 13 away from the base substrate.

In some embodiments of the present disclosure, the display substrate may be, for example, a liquid crystal display substrate, which includes an alignment film. In other optional embodiments, the display substrate may be, for example, an OLED display substrate, which may not include the alignment film.

In embodiments of the present disclosure, the driving structure layer includes GOA (Gate Driven on Array), that is, a gate driven integration on array substrate.

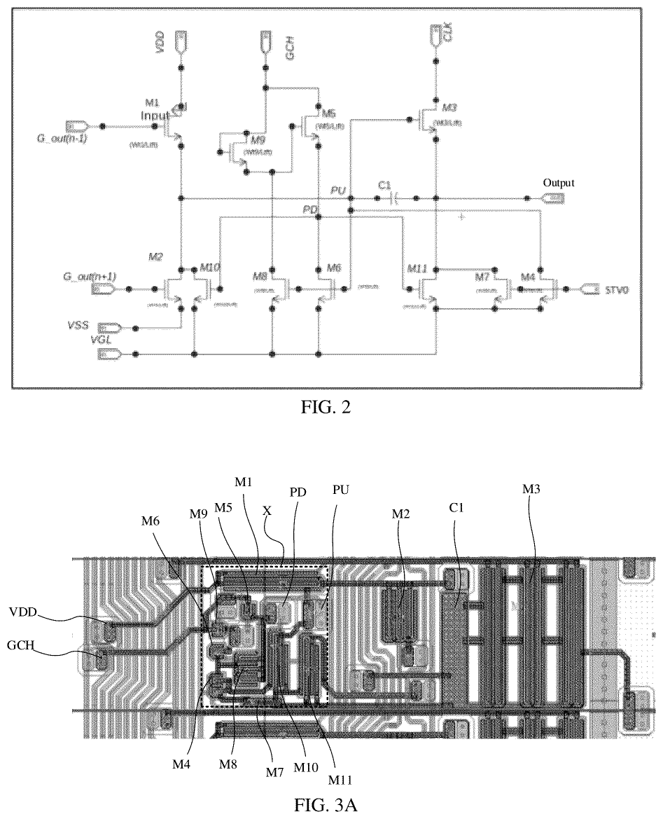

For example, the GOA included in the driving structure layer in the present disclosure is an 11T1C driving circuit. FIG. 2 shows an equivalent circuit diagram of a driving circuit of the display substrate according to embodiments of the present disclosure.

As shown in FIG. 2, the GOA driving circuit of such embodiments may include a clock signal terminal CLK, a first control signal terminal VDD, a second control signal terminal GCH, a third control signal terminal VGL, a fourth control signal terminal STV0, a fifth control signal terminal VSS, a signal terminal G_out (n+1), an input signal terminal Input, and a signal output terminal Output.

Specifically, the GOA driving circuit includes a first transistor M1, a second transistor M2, a third transistor M3, a fourth transistor M4, a fifth transistor M5, a sixth transistor M6, a seventh transistor M7, an eighth transistor M8, a ninth transistor M9, a tenth transistor M10, an eleventh transistor M11, and a bootstrap capacitor C1.

The first transistor M1 has a control electrode electrically connected to the input signal terminal Input, and the input signal terminal Input is electrically connected to the signal terminal G_out(n−1). The first transistor M1 has a first electrode electrically connected to the first control signal terminal VDD, and a second electrode electrically connected to a control electrode of the third transistor M3. The second transistor M2 has a control electrode electrically connected to the signal terminal G_out(n+1), a first electrode electrically connected to the second electrode of the first transistor, and a second electrode electrically connected to the fifth control signal terminal VSS. The third transistor M3 has a first electrode electrically connected to the clock signal terminal CLK, and a second electrode electrically connected to the bootstrap capacitor C1 and the signal output terminal Output. The fourth transistor M4 has a control electrode electrically connected to the fourth control signal terminal STV0, a first electrode electrically connected to a pull-up node PU which is electrically connected to the second electrode of the first transistor M1, and a second electrode electrically connected to the third control signal terminal VGL. The fifth transistor M5 has a control electrode electrically connected to a second electrode of the ninth transistor M9, a first electrode electrically connected to the second control signal terminal GCH, and a second electrode electrically connected to a control node PD. The sixth transistor M6 has a control electrode electrically connected to the pull-up node PU, a first electrode electrically connected to the control node PD, and a second electrode electrically connected to the third control signal terminal VGL. The seventh transistor M7 has a control electrode electrically connected to the fourth control signal terminal STV0, a first electrode electrically connected to the second electrode of the third transistor M3 and the signal output terminal Output, and a second electrode electrically connected to the third control signal terminal VGL. The eighth transistor M8 has a control electrode electrically connected to the pull-up node PU, a first electrode electrically connected to the second electrode of the ninth transistor M9, and a second electrode electrically connected to the third control signal terminal VGL. A control electrode and a first electrode of the ninth transistor M9 are electrically connected to the second control signal terminal GCH, and the second electrode of the ninth transistor M9 is electrically connected to the first electrode of the eighth transistor. The tenth transistor M10 has a control electrode electrically connected to the control node PD, a first electrode electrically connected to the second electrode of the first transistor, and a second electrode electrically connected to the third control signal terminal VGL. The eleventh transistor M11 has a control electrode electrically connected to the control node PD, a first electrode electrically connected to the signal output terminal Output, and a second electrode electrically connected to the third control signal terminal VGL.

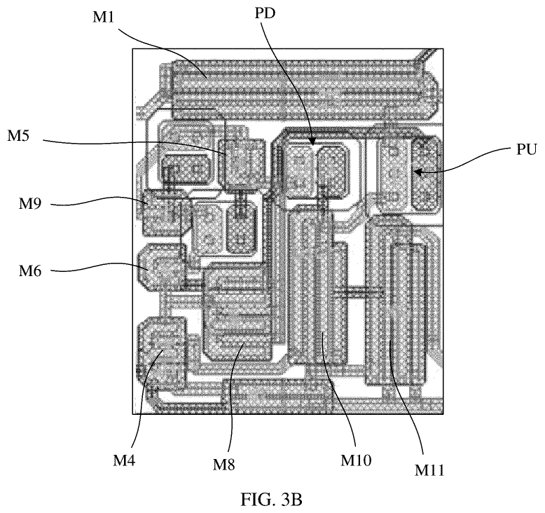

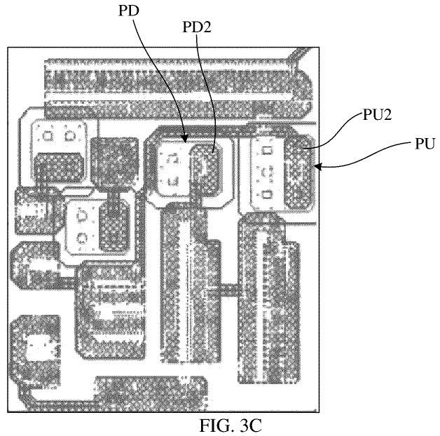

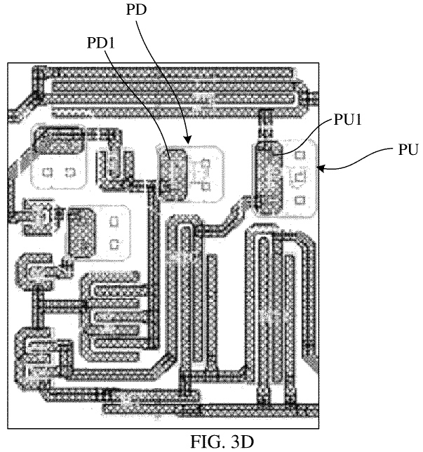

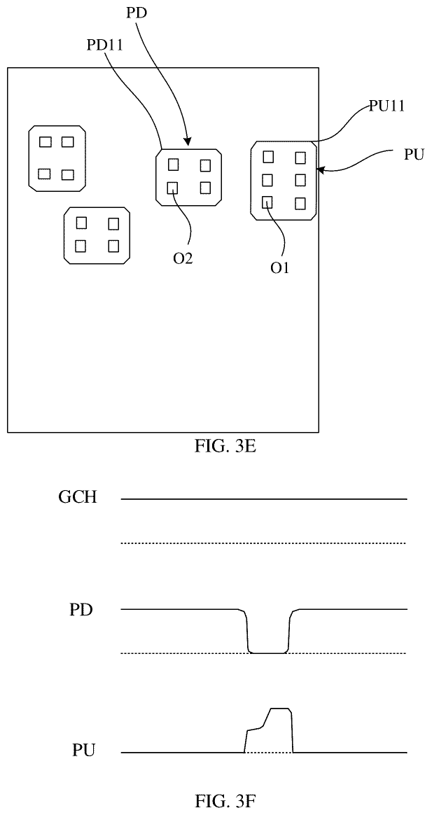

FIG. 3A shows a schematic structural diagram of a driving circuit of the display substrate according to an embodiment of the present disclosure. FIG. 3B shows a partially enlarged view of region X in FIG. 3A. FIG. 3C shows a schematic structural diagram of a gate layer in FIG. 3B. FIG. 3D shows a schematic structural diagram of a source/drain layer in FIG. 3B. FIG. 3E shows a schematic structural diagram of a conductive layer in FIG. 3B. FIG. 3F shows a timing diagram of a second control signal terminal and some nodes in FIG. 3A

As mentioned above, the pull-up node PU and the control node PD shown in FIG. 3A and FIG. 3B have different potentials, and the control node PD is electrically connected to the second control signal terminal GCH. As shown in FIG. 3F, for example, dashed lines may represent reference lines with zero potential, while solid lines represent changes of the potentials of the second control signal terminal GCH, the control node PD and the pull-up node PU over a time period with respect to the reference lines with zero potential. As shown in FIG. 3F, in some timing sequence within a time period, the potential of the control node PD is higher than the potential of the pull-up node PU, that is, in most of the time period, the potential of the control node PD is higher than the potential of the pull-up node PU. For example, a time period during which the potential of the control node PD is higher than the potential of the pull-up node PU is a first time period, and a time period during which the potential of the control node PD is lower than the potential of the pull-up node PU is a second time period. The first time period is greater than the second period. For example, a ratio of the first time period to the second time period is greater than or equal to 2. As shown in FIG. 3A, the distance between the pull-up node PU and the control node PD is small, and there is a potential difference between the pull-up node PU and the control node PD, for example, the potential of the control node PD is higher than the potential of the pull-up node PU for most of the time period. For example, the pull-up node PU may be the first electrode of the driving structure, and the control node PD may be the second electrode of the driving structure. A first conductor portion is provided at the pull-up node PU to connect the first conductive portion and the second conductive portion of the pull-up node PU, and a second conductor portion is provided at the control node PD to connect the third conductive portion and the fourth conductive portion of the control node PD (to be described below). When water molecules in the environment penetrate between the control node PD and the pull-up node PU, the first conductor portion at the low potential electrode is prone to electrolytic corrosion. It should be noted that herein, a bridging portion corresponding to the pull-up node PU is denoted as pull-up node PU, and a bridging portion corresponding to the control node PD is denoted as control node PD.

In embodiments of the present disclosure, the problem of corrosion caused by different potentials between different electrodes in the driving circuit may be solved by designing a size relationship between areas of the first conductor portion and the second conductor portion of the conductor layer respectively provided at the pull-up node PU and the control node PD.

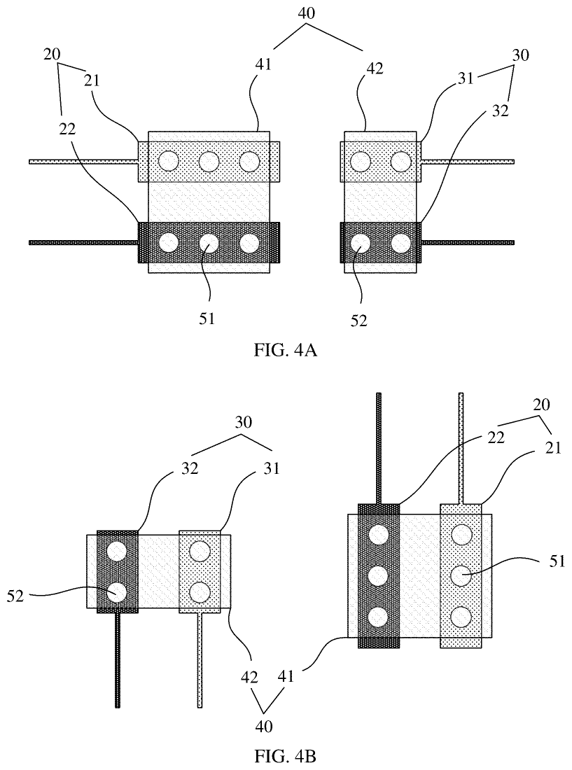

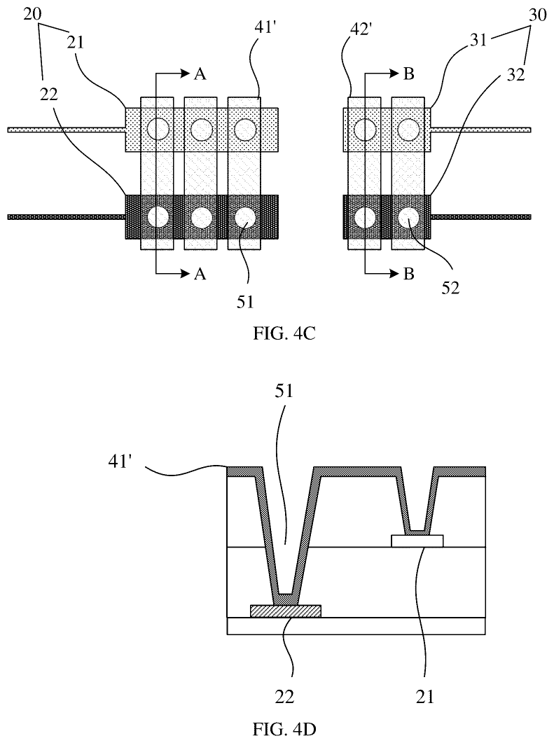

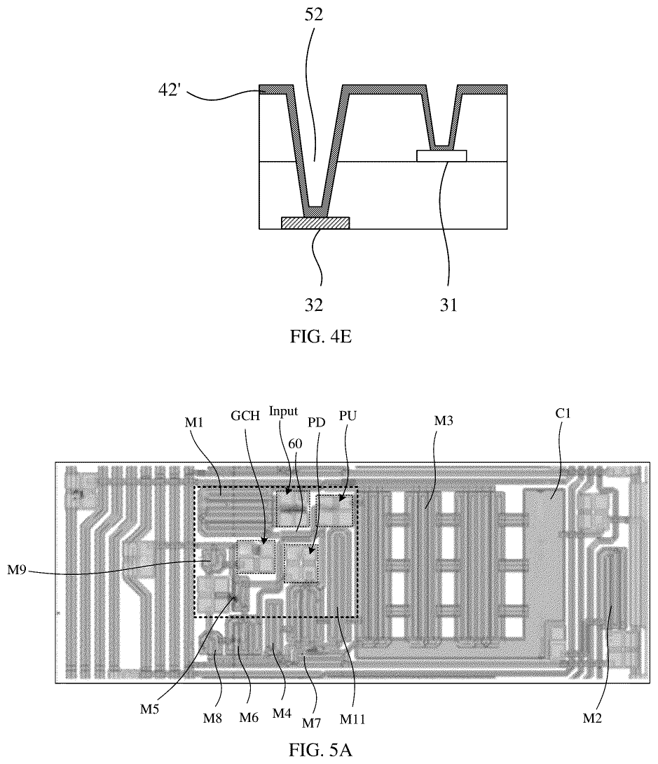

FIG. 4A shows a schematic structural diagram of a driving structure layer of the display substrate according to an embodiment of the present disclosure. FIG. 4B shows a schematic structural diagram of a driving structure layer of the display substrate according to another embodiment of the present disclosure. FIG. 4C shows a schematic structural diagram of a driving structure layer of the display substrate according to still another embodiment of the present disclosure.

As shown in FIG. 4A, FIG. 4B and FIG. 4C, the driving structure layer of embodiments of the present disclosure includes an electrode layer, which may be, for example, a multi-layer structure. The electrode layer includes at least one first electrode 20 and at least one second electrode 30 adjacent to each other in the non-display region. A potential of the first electrode 20 is lower than that of the second electrode 30, that is, the first electrode 20 is a low potential electrode, and the second electrode 30 is a high potential electrode.

A conductor layer 40 is located on a side of the electrode layer away from the base substrate. The conductor layer 40 includes a first conductor portion 41 electrically connected to the first electrode and a second conductor portion 42 electrically connected to the second electrode. The first conductor portion 41 and the second conductor portion 42 may be located in a same layer and connected to electrodes with different potentials, respectively.

An area of an orthographic projection of the first conductor portion 41 on the base substrate is greater than an area of an orthographic projection of the second conductor portion 42 on the base substrate.

In some embodiments of the present disclosure, the first conductor portion is connected to the first electrode 20, and the first electrode is a low potential electrode. As mentioned above, when water vapor penetrates into the driving structure layer, the low potential electrode may be corroded. As the first conductor portion 41 and the second conductor portion 42 are located in the same layer and the first conductor portion 41 has the same potential as the first electrode, the first conductor portion 41 is prone to corrosion.

During a corrosion process, a corrosion rate of the low potential electrode is directly proportional to a current between electrodes, which may be expressed by the following equation:

$${I}_{g} = {I}_{L} * {S}_{a} / {S}_{c}$$

where I_{g} represents an electrode current intensity, I_{L} represents a limit diffusion current density, S_{c} represents an area of the low potential electrode, and Sₐ represents an area of the high potential electrode. According to the above equation, the larger the surface area of the low potential electrode, the smaller the electrode current intensity, and then the corrosion rate is smaller.

In embodiments of the present disclosure, with the design that the area of the orthographic projection of the first conductor portion 41 on the base substrate is greater than the area of the orthographic projection of the second conductor portion 42 on the base substrate, it is possible to effectively reduce the corrosion rate of the low potential electrode, and by increasing the surface area of the low potential electrode, it is possible to significantly prolong the service life of the display substrate.

As shown in FIG. 4A and FIG. 4B, the first conductor portion 41 is connected to the first electrode 20 through a first via hole 51, and the second conductor portion 42 is connected to the second electrode 30 through a second via hole 52. Embodiments shown in FIG. 3A will be described in detail with reference to FIG. 3A to FIG. 3E, FIG. 4A, FIG. 4B and FIG. 4C.

In some exemplary embodiments in the present disclosure, the number of first via holes 51 is proportional to the area of the orthographic projection of the first conductor portion 41 on the base substrate. For example, the larger the area of the orthographic projection of the first conductor portion on the base substrate, the greater the number of first via holes. By increasing the number of via holes, it is possible to effectively reduce a resistance of the first conductor portion during operation.

For example, the area of the orthographic projection of the first conductor portion on the base substrate is greater than the area of the orthographic projection of the second conductor portion on the base substrate, the number of first via holes connecting the first conductor portion and the first electrode is greater than the number of second via holes connecting the second conductor portion and the second electrode.

In an exemplary embodiment, the orthographic projection of the first conductor portion on the base substrate overlaps with the orthographic projection of the first electrode on the base substrate to form a first overlapping region.

In another exemplary embodiment, the orthographic projection of the second conductor portion on the base substrate overlaps with the orthographic projection of the second electrode on the base substrate to form a second overlapping region.

As shown in FIG. 4A, FIG. 4B and FIG. 4C, an orthographic projection of the first via hole 51 on the base substrate is located in the first overlapping region, and an orthographic projection of the second via hole 52 on the base substrate is located in the second overlapping region.

For example, as shown in FIG. 4A and FIG. 4B, a first conductor portion 41 is provided to electrically connect the first electrode 20, and a second conductor portion 42 is provided to electrically connect the second electrode 30. A difference between embodiments shown in FIG. 4A and embodiments shown in FIG. 4B lies in that the first electrode and the second electrode are arranged in different directions, and the directions may be adjusted in any way according to actual design needs. For example, as shown in FIG. 4B, the first conductive portion 21 and the second conductive portion 22 of the first electrode 20 and the third conductive portion 31 and the fourth conductive portion 32 of the second electrode 30 are alternately arranged in different layers. For example, the first conductive portion 21 is located in the SD layer, the second conductive portion 22 is located in the Gate layer, the third conductive portion 31 is located in the SD layer, and the fourth conductive portion 32 is located in the Gate layer, so that a distance between the conductive portions of different electrodes may be increased, and a mutual influence may be reduced.

For example, as shown in FIG. 4C, a plurality of first conductor portions 41′ is provided to electrically connect the first electrode 20, and a plurality of second conductor portions 42′ is provided to electrically connect the second electrode 30. Each first conductor portion 41′ is connected to first via holes 51 of the first electrode in different driving structure layers. A side of the first conductor portion away from the base substrate is covered by other insulating material layers. In a case of a plurality of first conductor portions, when other film layers such as an insulating layer is provided, the plurality of first conductor portions are separated by the insulating layer. When water molecules penetrate into one of the first conductor portions, as other first conductor portions are separated from that first conductor portion by the insulating layer, the water molecules may be effectively prevented from penetrating into other first conductor portions, and during use, water molecules in the environment may be effectively prevented from entering the film layer where the first conductor portion is located, so as to increase a resistance of water molecules entering the first conductor portion. For example, if one of the plurality of first conductor portions 41′ is corroded, as other first conductor portions close to the corroded first conductor portion are separated from the corroded first conductor portion by insulating materials, the water molecules may be prevented from further spreading into other un-corroded first conductor portions. Through such arrangement, the corrosion rate of the first electrode with low potential may be reduced, and the service life of the display substrate may be prolonged.

FIG. 4D shows a schematic cross-sectional structural diagram of the driving structure layer taken along line A-A in FIG. 4C. FIG. 4E shows a schematic cross-sectional structural diagram of the driving structure layer taken along line B-B in FIG. 4C.

In embodiments shown in FIG. 4C to FIG. 4E, the first electrode and the second electrode include a plurality of conductor portions for electrically connecting the first electrode and electrically connecting the second electrode, respectively.

For example, as shown in FIG. 4D, the first electrode 20 includes a first conductive portion 21 and a second conductive portion 22, and the first conductive portion 21 and the second conductive portion 22 are located in different layers. For example, the first conductive portion 21 is located in the source/drain layer (e.g., SD layer), and the second conductive portion 22 is located in the gate layer (e.g., Gate layer). The first conductive portion 21 and the second conductive portion 22 are electrically connected through the first conductor portion 41′.

For example, as shown in FIG. 4E, the second electrode 30 includes a third conductive portion 31 and a fourth conductive portion 32, and the third conductive portion 31 and the fourth conductive portion 32 are located in different layers. For example, the third conductive portion 31 is located in the source/drain layer (e.g., SD layer), and the fourth conductive portion 32 is located in the gate layer (e.g., Gate layer). The third conductive portion 31 and the fourth conductive portion 32 are electrically connected through the second conductor portion 42′.

In some exemplary embodiments of the present disclosure, the first conductive portion 21 and the third conductive portion 31 are located in a same layer, and the second conductive portion 22 and the fourth conductive portion 32 are located in a same layer. According to such arrangement, it is convenient to etch the first electrode and the second electrode through a patterning process, and the manufacturing cost may be effectively reduced.

In other optional embodiments, the first electrode 20 may include more conductive portions, which are electrically connected through the first conductor portion 41′. The second electrode 30 may include more conductive portions, which are electrically connected through the second conductor portion 42′.

In other optional embodiments, the plurality of conductive portions of the first electrode and the plurality of conductive portions of the second electrode may be located in a same layer or in different layers. At least part of the first conductor portion used to electrically connect the first electrode and at least part of the second conductor portion used to electrically connect the second electrode are located in a same layer, and an area of an orthographic projection of the first conductor portion located in the same layer on the base substrate is greater than an area of an orthographic projection of the second conductor portion located in the same layer on the base substrate.

In embodiments of the present disclosure, the driving circuit of embodiments in FIG. 3A will be described in detail with reference to FIG. 3A to FIG. 3E and FIG. 4A to FIG. 4C.

The structure of the driving circuit of the display substrate shown in FIG. 3A and FIG. 3B includes the control node PD and the pull-up node PU. In most of the time period, the potential of the control node PD is higher than that of the pull-up node PU, that is, the pull-up node PU is the first electrode with low potential, and the control node PD is the second electrode with high potential. As shown in FIG. 3A, the schematic structural diagram of the driving circuit shows a first conductive portion PU1 and a second conductive portion PU2 of the pull-up node PU, and the first conductive portion PU1 and the second conductive portion PU2 are located in different layers. As shown in FIG. 3C and FIG. 3D, the first conductive portion PU1 is located in the source/drain layer (e.g., SD layer), and the second conductive portion PU2 is located in the gate layer (e.g., Gate layer). The schematic structural diagram of the driving circuit further shows a third conductive portion PD1 and a fourth conductive portion PD2 of the control node PD, and the third conductive portion PD1 and the fourth conductive portion PD2 are located in different layers. As shown in FIG. 3C and FIG. 3D, the third conductive portion PD1 is located in the source/drain layer (e.g., SD layer), and the fourth conductive portion PD2 is located in the gate layer (e.g., Gate layer). The schematic structural diagram of the driving circuit further shows a first conductor portion PU11 used to connect the first conductive portion PU1 and the second conductive portion PU2, and a second conductor portion PD11 used to connect the third conductive portion PD1 and the fourth conductive portion PD2. For example, the first conductor portion PU11 is electrically connected to the first conductive portion PU1 and the second conductive portion PU2 through a via hole O1, and the second conductor portion PD11 is electrically connected to the third conductive portion PD1 and the fourth conductive portion PD2 through a via hole O2. The first conductor portion PU11 and the second conductor portion PD11 may be, for example, metal oxide layers located in a same layer, such as indium tin oxide (ITO).

As shown in FIG. 2 and FIG. 3A, the pull-up node PU is electrically connected to the input signal terminal Input, and the control node PD is electrically connected to the second control signal terminal GCH. During most of the operation of driving circuit, the level of the pull-up node PU is lower than that of the control node PD. As the pull-up node PU is close to the control node PD, in order to solve the problem of the electrochemical corrosion caused by water penetration in the conductor portion at the PU node, the first conductor portion and the second conductor portion may be provided so that the area of the orthographic projection of the first conductor portion connected to the first electrode of the pull-up node PU on the base substrate is greater than the area of the orthographic projection of the second conductor portion connected to the control node PD on the base substrate, thereby effectively avoiding the failure problem caused by corrosion of the pull-up node PU with low potential.

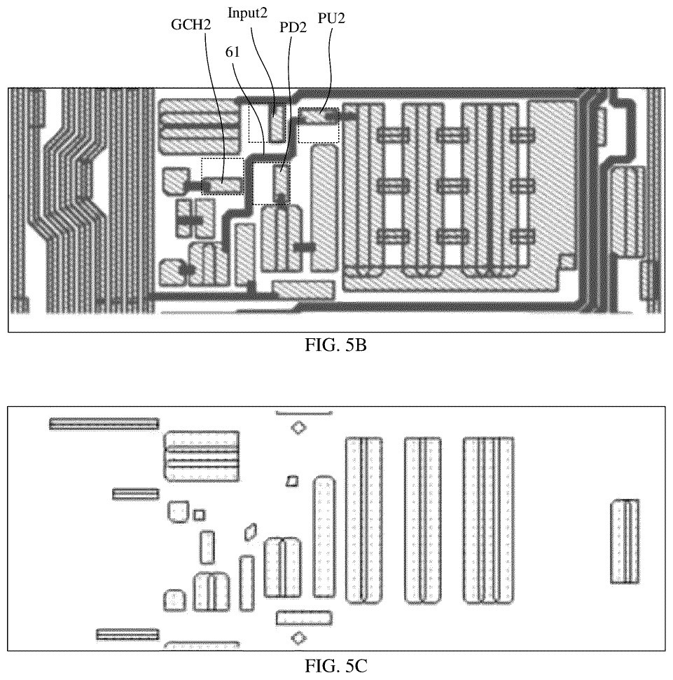

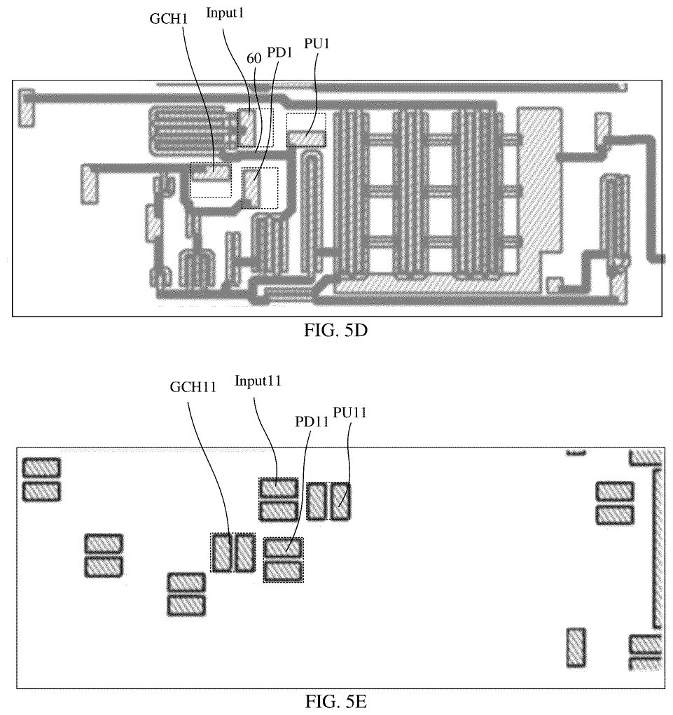

FIG. 5A shows a schematic structural diagram of a driving circuit of a display substrate according to another embodiment of the present disclosure. FIG. 5B shows a schematic structural diagram of a gate layer in FIG. 5A. FIG. 5C shows a schematic structural diagram of an active layer in FIG. 5A. FIG. 5D shows a schematic structural diagram of a source/drain layer in FIG. 5A. FIG. 5E shows a schematic structural diagram of a conductive layer in FIG. 5A.

A detailed explanation of the structure of embodiments in FIG. 5A is provided with reference to the equivalent circuit diagram in FIG. 2 and the structure of the driving circuit shown in FIG. 5A to FIG. 5E.

For example, as shown in FIG. 5A, the structure of the driving circuit in such embodiments includes an input signal terminal Input. The input signal terminal Input includes a first conductive portion Input1 and a second conductive portion Input2, which are electrically connected through a first conductor portion Input11. The pull-up node PU includes a first conductive portion PU1 and a second conductive portion PU2, which are electrically connected through a first conductor portion PU11. The second control signal terminal GCH includes a third conductive portion GCH1 and a fourth conductive portion GCH2, which are electrically connected through a second conductor portion GCH11. The control node PD includes a third conductive portion PD1 and a fourth conductive portion PD2, which are electrically connected through a second conductor portion PD11.

For example, as shown in FIG. 5C, the first conductive portion Input1 of the input signal terminal Input and the first conductive portion PU1 of the pull-up node PU are electrically connected through a third electrode 60 described below. The input signal terminal Input may have, for example, the same potential as the pull-up node PU.

As shown in FIG. 5D, the third conductive portion GCH1 of the second control signal terminal GCH is electrically connected to the third conductive portion PD1 of the control node PD, and the second control signal terminal GCH has the same potential as the control node PD.

For example, as shown in FIG. 5B, a wire 61 electrically connected to the pull-up node PU is provided between the input signal terminal Input and the pull-up node PU that have a low potential and the second control signal terminal GCH and the control node PD that have a high potential. The wire 61 may also achieve, for example, the same effect as the third electrode 60 described below.

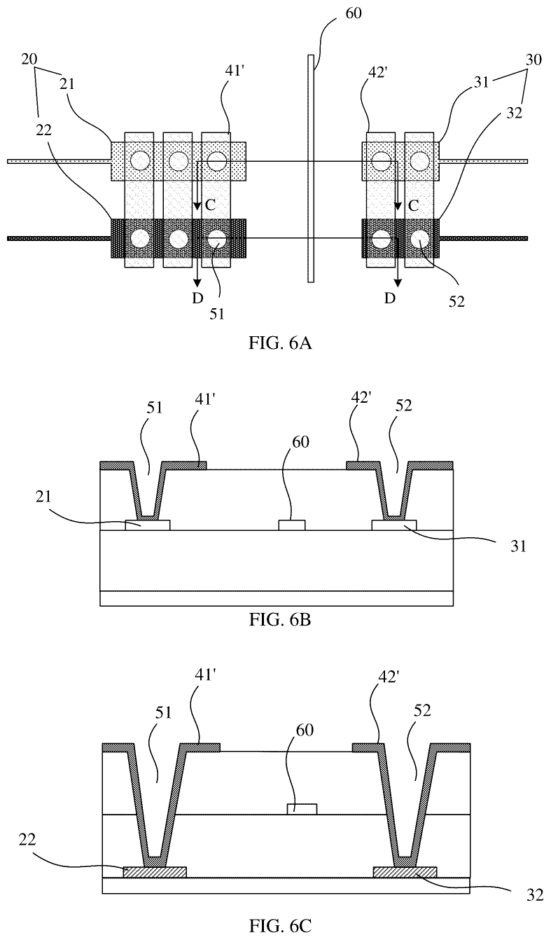

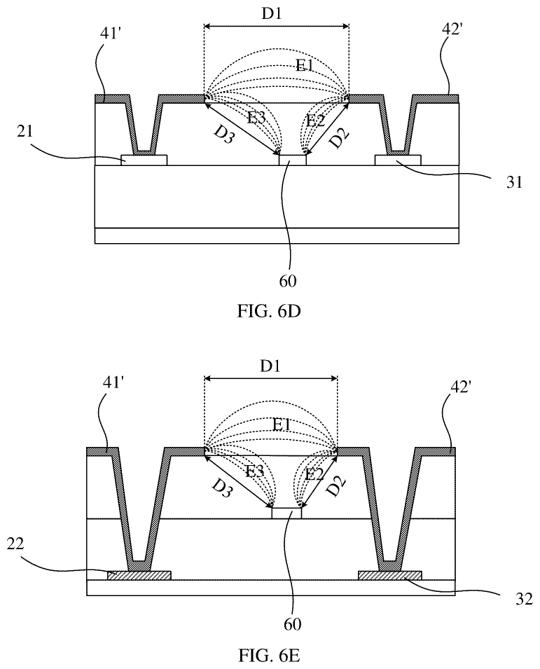

FIG. 6A shows a schematic structural diagram of a driving structure layer of a display substrate according to still another embodiment of the present disclosure. FIG. 6B shows a schematic cross-sectional structural diagram of the driving structure layer taken along line C-C in FIG. 6A. FIG. 6C shows a schematic cross-sectional structural diagram of the driving structure layer taken along line D-D in FIG. 6A. FIG. 6D shows a schematic diagram of a distribution of electric field lines in FIG. 6B. FIG. 6E shows a schematic diagram of a distribution of electric field lines in FIG. 6C.

As shown in FIG. 6A, the electrode layer further includes the third electrode 60. The third electrode 60 is located between the first electrode 20 and the second electrode 30. For example, as shown in FIG. 6B, the third electrode 60 is located between the first conductive portion 21 of the first electrode 20 and the third conductive portion 31 of the second electrode 30. As shown in FIG. 6C, the third electrode 60 is located between the second conductive portion 22 of the first electrode 20 and the fourth conductive portion 32 of the second electrode 30.

In some embodiments of the present disclosure, the third electrode is insulated from the second conductor portion. The third electrode is located in the same layer as the first electrode or the second electrode.

In other embodiments of the present disclosure, the third electrode is located in a different layer from the first electrode or the second electrode.

For example, as shown in FIG. 6B, the third electrode 60 may be provided in the same layer as the first conductive portion 21 of the first electrode 20 and the third conductive portion 31 of the second electrode 30. By providing an insulating layer on the third electrode 60, the first conductive portion 21 of the first electrode 20 and the third conductive portion 31 of the second electrode 30, the third electrode 60 may be insulated from the first conductive portion 21 of the first electrode 20 and the third conductive portion 31 of the second electrode 30.

For example, as shown in FIG. 6C, the third electrode 60 may be provided in a different layer from the second conductive portion 22 of the first electrode 20 and the fourth conductive portion 32 of the second electrode 30. One or more insulating layers may be provided between different layers, so that the third electrode 60 may be insulated from the second conductive portion 22 of the first electrode 20 and the fourth conductive portion 32 of the second electrode 30.

In embodiments of the present disclosure, the potential of the third electrode is lower than that of the second electrode.

For example, the potential of the third electrode is lower than that of the second electrode, and the potential of the third electrode is lower than that of the first electrode.

For example, the potential of the third electrode is lower than that of the second electrode, and the potential of the third electrode is higher than that of the first electrode, that is, the potential of the third electrode is between the potential of the second electrode and the potential of the first electrode.

For example, the potential of the third electrode is equal to the potential of the first electrode. In an optional embodiment, the third electrode is electrically connected to the first electrode, so that the potential of the third electrode is equal to the potential of the first electrode. In another optional embodiment, the potential of the third electrode is equal to the potential of the first electrode, and the third electrode has a non-electrical connection relationship with the first electrode.

When there is a potential difference between different electrodes, an electric field is generated, and multiple electric fields interfere with each other. For example, an electric field intensity between electrodes with a large potential difference may be greater than an electric field intensity between electrodes with a small potential difference. By rationally designing the interference between different electric fields, it is possible to suppress the problem of electrochemical corrosion between the first conductor portion for the first electrode and the second conductor portion for the second electrode.

In embodiments of the present disclosure, by providing the third electrode between the first electrode and the second electrode and setting the potential of the third electrode to be lower than that of the second electrode, an electric field may be generated between the third electrode and the second electrode to interfere with the electric field between the first conductor portion for the first electrode and the second conductor portion for the second electrode, so as to suppress the problem of failure caused by the electrochemical corrosion at the first conductor portion for the first electrode.

FIG. 6D and FIG. 6E exemplarily show schematic diagrams of the third electrode interfering with the electric field between the first conductor portion for the first electrode and the second conductor portion for the second electrode according to embodiments of the present disclosure.

For example, as shown in FIG. 6D, the potential of the first electrode 20 is lower than that of the second electrode 30, the first conductive portion 21 of the first electrode 20 is electrically connected to the first conductor portion 41′, the third conductive portion 31 of the second electrode 30 is electrically connected to the second conductor portion 42′, and the electric field intensity between the first conductor portion 41′ and the second conductor portion 42′ is E1. The potential of the third electrode 60 is lower than that of the second electrode 30, and the electric field intensity between the third electrode 60 and the second conductor portion 42′ is E2. When there is a potential difference between the third electrode 60 and the first electrode 20, the electric field intensity between the third electrode 60 and the first conductor portion 41′ is E3. The electric field may produce a Lorentz force on moving electrons. When the Lorentz force of the electric field inhibits a movement of electrons towards the cathode, the electrochemical corrosion effect generated during the operation of the display substrate may be suppressed.

In exemplary embodiments of the present disclosure, the electric field intensity E2 between the third electrode 60 and the second conductor portion 42′ is set to be greater than the electric field intensity E1 between the first conductor portion 41′ and the second conductor portion 42′. When electrons move from the second conductor portion 42′ to the first conductor portion 41′, the force of the electric field E2 may inhibit the movement of electrons, so that the electrochemical corrosion of the first conductor portion may be effectively prevented.

In some exemplary embodiments of the present disclosure, a plurality of third electrodes may be provided, which may include, for example, the wire 61 shown in FIG. 5B and the third electrode 60 shown in FIG. 5D.

In exemplary embodiments of the present disclosure, during the operation of the GOA driving circuit, the electric field intensity between the first conductor portion 41′ and the second conductor portion 42′ may be expressed as E=U/D, where U represents a potential difference between the first conductor portion and the second conductor portion, and D represents a distance between the first conductor portion and the second conductor portion. According to the above equation, as the distance between the first conductor portion and the second conductor portion increases, the electric field intensity E may be weakened, and a rate of an electron migration that causes the electrochemical corrosion may decrease, so that a corrosion rate may be effectively reduced.

As shown in FIG. 6D and FIG. 6E, the distance between the first conductor portion 41′ and the second conductor portion 42′ is D1, the distance between the third electrode 60 and the second conductor portion 42′ is D2, and the distance between the third electrode and the first conductor portion 41′ is D3.

According to the above-mentioned relationship between the electric field intensity and the distance between electrodes with different potentials, the distance D2 between the third electrode 60 and the second conductor portion 42′ may be set to be less than the distance D1 between the first conductor portion 41′ and the second conductor portion 42′, so that the electric field between the third electrode and the second conductor portion 42′ may suppress the electron migration between the first conductor portion 41′ and the second conductor portion 42′, and the problem of electrochemical corrosion between the first conductor portion and the second conductor portion may be suppressed.

In some optional embodiments of the present disclosure, the distance between the first conductor portion and the second conductor portion may be increased to suppress the electrochemical corrosion between the first conductor portion and the second conductor portion, so as to prolong the service life of the display substrate.

In the structure of the driving circuit shown in FIG. 5A to FIG. 5E, the input signal terminal Input and the pull-up node PU are equivalent to the first electrode shown in FIG. 6A and have a low potential, while the second control signal terminal GCH and the control node PD are equivalent to the second electrode shown in FIG. 6A and have a high potential. As shown in FIG. 5A, the third electrode 60 may be a source/drain layer (e.g., SD layer) that electrically connects the input signal terminal Input and the pull-up node PU, and the third electrode 60 is located between the input signal terminal Input/the pull-up node PU and the second control signal terminal GCH/the control node PD to interfere with the electric field between the input signal terminal Input and the pull-up node PU that have a low potential and the second control signal terminal GCH and the control node PD that have a high potential, so as to effectively suppress the problem of the electrochemical corrosion at the input signal terminal Input and the pull-up node PU that have a low potential.

In embodiments of the present disclosure, as shown in FIG. 5A, the electrode layer includes a plurality of first electrodes, such as the input signal terminal Input and the pull-up node PU. The plurality of first electrodes are connected through the third electrode. In other optional embodiments, the plurality of first electrodes may be partially connected through the third electrode or partially not connected through the third electrode, and the plurality of first electrodes may have the same potential.

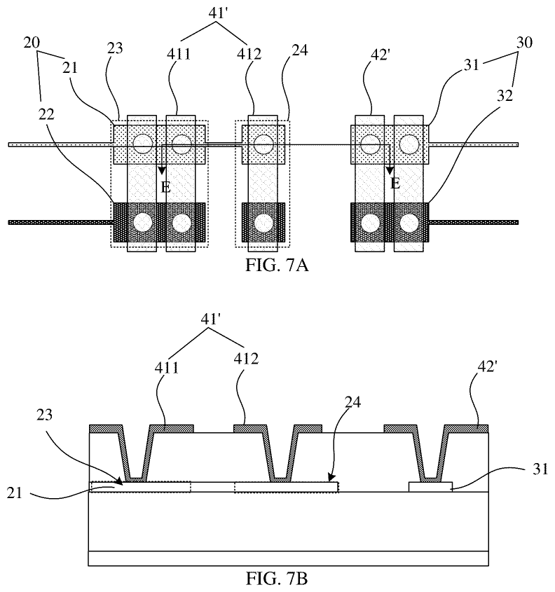

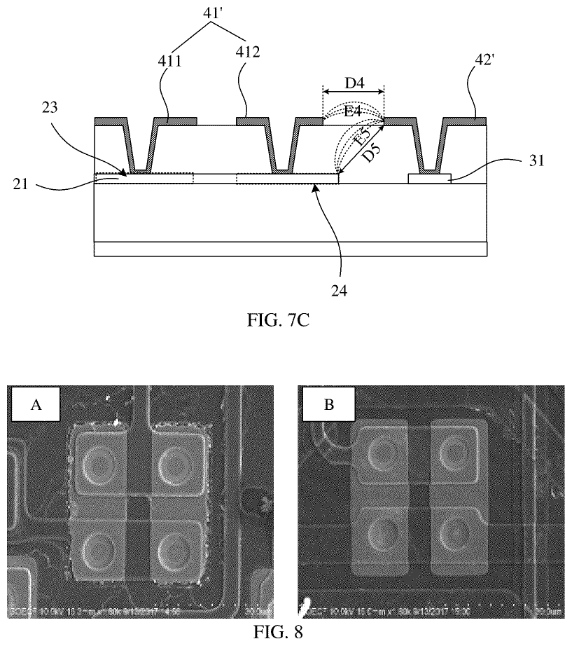

FIG. 7A shows a schematic structural diagram of a driving structure layer of a display substrate according to yet another embodiment of the present disclosure. FIG. 7B shows a schematic cross-sectional structural diagram of the driving structure layer taken along line E-E in FIG. 7A. FIG. 7C shows a schematic diagram of a distribution of electric field lines in FIG. 7B.

In the driving structure layer of the display substrate shown in FIG. 7A to FIG. 7C, the first electrode 20 includes a first non-redundant electrode 23 and a first redundant electrode 24, as shown in the dashed boxes in FIG. 7A. The first conductor portion 41′ includes a first non-redundant conductor portion 411 electrically connected to the first non-redundant electrode and a first redundant conductor portion 412 electrically connected to the first redundant electrode.

The first redundant electrode 24 is located between the first non-redundant electrode 23 and the second electrode 30. For example, as shown in FIG. 7B, the first redundant electrode 24 is located between the first non-redundant electrode 23 and the third conductive portion 31 of the second electrode 30.

A potential of the first redundant electrode 24 is the same as that of the first non-redundant electrode 23.

In exemplary embodiments, the first redundant electrode 24 and the first non-redundant electrode 23 are electrically connected to achieve the same potential. In optional embodiments, the first redundant electrode 24 and the first non-redundant electrode 23 may not be electrically connected while maintaining the same potential.

For example, the first redundant electrode 24 is electrically connected to the first non-redundant electrode 23. As shown in FIG. 7A and FIG. 7B, the first redundant electrode 24 is electrically connected to the first conductive portion 21 of the first non-redundant electrode 23. In optional embodiments, the electrical connection between the first redundant electrode and the first non-redundant electrode may also be, for example, an electrical connection between the second conductive portion 22 of the first non-redundant electrode 23 and the first redundant electrode 24.

For example, the first conductive portion of the first redundant electrode is connected to the first conductive portion of the first non-redundant electrode; and/or the second conductive portion of the first redundant electrode is connected to the second conductive portion of the first non-redundant electrode.

In exemplary embodiments of the present disclosure, as shown in FIG. 7A, the first conductor portion 41′ includes a first non-redundant conductor portion 411 electrically connected to the first non-redundant electrode 23 and a first redundant conductor portion 412 electrically connected to the first redundant electrode 24.

As the potential of the first electrode is lower than that of the second electrode, during the operation of the display substrate, electrons move from the second conductor portion electrically connected to the second electrode to the first conductor portion electrically connected to the first electrode, resulting in an electrochemical corrosion of the first conductor portion. In such embodiments, the first redundant conductor portion 412 is provided so that the first redundant conductor portion 412 preferentially acquires electrons from the second conductor portion 42′ and undergoes an electrochemical reaction. As the first redundant conductor portion 412 is not a component for an electrical connection, even if the first redundant conductor portion 412 is corroded, it will not cause the failure of the display substrate, so that the service life of the display substrate may be effectively improved.

In some exemplary embodiments of the present disclosure, as mentioned above, the distance between electrodes may affect the corrosion rate of the electrodes. In a case of a fixed potential difference, the larger the distance between electrodes, the less the corrosion rate.

In such embodiments, as shown in FIG. 7C, a distance D4 exists between the first redundant conductor portion 412 and the second conductor portion 42′, and a distance D5 exists between the first redundant electrode 24 and the second conductor portion 42′.

As the first redundant conductor portion 412 is electrically connected to the first redundant electrode 24, the potential of the first redundant conductor portion 412 is the same as that of the first redundant electrode 24. An electric field intensity E4 exists between the first redundant conductor portion 412 and the second conductor portion 42′, and an electric field intensity E5 exists between the first redundant electrode 24 and the second conductor portion 42′.

For example, the distance D4 between the first redundant conductor portion 412 and the second conductor portion 42′ is greater than the distance D5 between the first redundant electrode 24 and the second conductor portion 42′.

For example, the electric field intensity E4 between the first redundant conductor portion 412 and the second conductor portion 42′ is less than the electric field intensity E5 between the first redundant electrode 24 and the second conductor portion 42′.

In such embodiments, by setting the distance D4 between the first redundant conductor portion 412 and the second conductor portion 42′ to be greater than the distance D5 between the first redundant electrode and the second conductor portion, the electric field intensity E5 between the first redundant electrode 24 and the second conductor portion 42′ may be greater than the electric field intensity E4 between the first redundant conductor portion 412 and the second conductor portion 42′, so that the corrosion rate of the first redundant conductor portion 412 may be reduced, and the service life of the display substrate may be prolonged.

In some exemplary embodiments of the present disclosure, the first conductor portion and the second conductor portion include a metal oxide or a metal. For example, the first redundant conductor portion, the first non-redundant conductor portion and the second conductor portion may include tin indium oxide.

In other exemplary embodiments of the present disclosure, the electrode layer further includes at least one fourth electrode and at least one fifth electrode in the non-display region, and the fourth electrode and the fifth electrode are adjacent to each other. A potential difference between the fourth electrode and the fifth electrode is less than the potential difference between the first electrode and the second electrode, and a distance between the fourth electrode and the fifth electrode is less than the distance between the first electrode and the second electrode.

For example, if the potential difference between the fourth electrode and the fifth electrode is small, for example, less than the potential difference between the first electrode and the second electrode, then the electric field between the fourth electrode and the fifth electrode may be small. By reducing the distance between the fourth electrode and the fifth electrode, it is possible to further reduce the distance between electrodes in a case that the corrosion between the fourth electrode and the fifth electrode meets a usage requirement, so as to achieve a requirement for narrow bezel.

In exemplary embodiments of the present disclosure, the distance between the first electrode and the second electrode may be designed according to a magnitude of the potential difference between the first electrode and the second electrode. For example, when the display substrate requires a long service life, it is possible to reduce the potential difference between the first electrode and the second electrode or increase the distance between the first electrode and the second electrode to meet the above requirement.

FIG. 8 shows a comparison diagram between a corrosion effect on an existing driving structure layer and a corrosion effect on the driving structure layer of the display substrate according to embodiments of the present disclosure.

Picture A and picture B in FIG. 8 show driving structure layers with the same usage environment and same usage time. Picture A in FIG. 8 shows a corrosion case of the first conductor portion connected to the first electrode in the existing driving structure layer during use, in which a corrosion occurring on a peripheral side of the first conductor portion results in an uneven corrosion region. Picture B in FIG. 8 shows that there is no corrosion around the first conductor portion for the first electrode of the display substrate in embodiments of the present disclosure, that is, there is no significant change around the first conductor portion. Therefore, the display substrate of embodiments of the present disclosure may effectively prevent an electrochemical corrosion of a low potential electrode, so that the service life of the display substrate may be prolonged.

In another aspect of the present disclosure, a display device is further provided, which includes the display substrate as described above.

Beneficial effects that the display device in the above embodiments of the present disclosure may achieve are the same as the beneficial effects that the above-mentioned display substrate may achieve, which will not be repeated here.

The above-mentioned display device may be any device that displays a moving image (such as video) or a fixed image (such as still image) and that displays a text or an image. More specifically, it is expected that the embodiments may be implemented in or associated with various electronic devices. The various electronic devices may include (but not be limited to) mobile phone, wireless device, personal data assistant (PDA), handheld or portable computer, GPS receiver/navigator, camera, MP4 video player, video camera, game console, watch, clock, calculator, television monitor, flat panel display, computer monitor, vehicle display (such as odometer display), navigator, cockpit controller and/or display, display for camera view (such as display of rear view camera in vehicle), electronic photo, electronic billboard or sign, projector, architectural structure, packaging and aesthetic structure (such as display for image of jewelry), etc.

Although some embodiments of the overall concept of the present disclosure have been illustrated and explained, those ordinary skilled in the art may understand that changes may be made to those embodiments without departing from a principle and spirit of the overall inventive concept. The scope of the present disclosure is limited by the claims and their equivalents.

1. A display substrate, comprising:
a base substrate; and
a driving structure layer on a side of the base substrate,
wherein the display substrate comprises a display region and a non-display region, and
wherein the driving structure layer comprises:
an electrode layer comprising at least one first electrode and at least one second electrode adjacent to each other in the non-display region, wherein a potential of the first electrode is lower than a potential of the second electrode, and
a conductor layer, wherein the conductor layer and the electrode layer are in different layers, and the conductor layer comprises a first conductor portion electrically connected to the first electrode and a second conductor portion electrically connected to the second electrode,
wherein an area of an orthographic projection of the first conductor portion on the base substrate is greater than an area of an orthographic projection of the second conductor portion on the base substrate.

2. The display substrate according to claim 1, wherein the first electrode comprises a first conductive portion and a second conductive portion, the first conductive portion and the second conductive portion are in different layers, and the first conductive portion and the second conductive portion are electrically connected through the first conductor portion,
wherein the second electrode comprises a third conductive portion and a fourth conductive portion, the third conductive portion and the fourth conductive portion are in different layers, and the third conductive portion and the fourth conductive portion are electrically connected through the second conductor portion, and
wherein the first conductive portion and the third conductive portion are in a same layer, and the second conductive portion and the fourth conductive portion are in a same layer.

3. The display substrate according to claim 2, wherein the electrode layer further comprises a third electrode,
wherein the third electrode is between the first electrode and the second electrode, and the third electrode is insulated from the second conductor portion, and
wherein a potential of the third electrode is lower than the potential of the second electrode.

4. The display substrate according to claim 3, wherein the third electrode is in a same layer as the first conductive portion or the second conductive portion.

5. The display substrate according to claim 3, wherein the third electrode is electrically connected to the first electrode, and the potential of the third electrode is the same as the potential of the first electrode.

6. The display substrate according to claim 3, wherein an electric field intensity between the third electrode and the second conductor portion is greater than an electric field intensity between the first conductor portion and the second conductor portion.

7. The display substrate according to claim 5, wherein a distance between the third electrode and the second conductor portion is less than a distance between the first conductor portion and the second conductor portion.

8. The display substrate according to claim 3, wherein the electrode layer comprises a plurality of first electrodes electrically connected through the third electrode.

9. The display substrate according to claim 2, wherein the first electrode comprises a first non-redundant electrode and a first redundant electrode, and
wherein the first conductor portion comprises a first non-redundant conductor portion electrically connected to the first non-redundant electrode and a first redundant conductor portion electrically connected to the first redundant electrode.

10. The display substrate according to claim 9, wherein the first redundant electrode is between the first non-redundant electrode and the second electrode.

11. The display substrate according to claim 10, wherein a potential of the first redundant electrode is the same as a potential of the first non-redundant electrode.

12. The display substrate according to claim 11, wherein the first redundant electrode is electrically connected to the first non-redundant electrode.

13. The display substrate according to claim 9, wherein a first conductive portion of the first redundant electrode is connected to a first conductive portion of the first non-redundant electrode; and/or
wherein a second conductive portion of the first redundant electrode is connected to a second conductive portion of the first non-redundant electrode.

14. The display substrate according to claim 13, wherein the first conductor portion comprises a first non-redundant conductor portion electrically connected to the first non-redundant electrode and a first redundant conductor portion electrically connected to the first redundant electrode.

15. The display substrate according to claim 14, wherein a distance between the first redundant conductor portion and the second conductor portion is greater than a distance between the first redundant electrode and the second conductor portion; and/or
wherein an electric field intensity between the first redundant conductor portion and the second conductor portion is less than an electric field intensity between the first redundant electrode and the second conductor portion.

16. (canceled)

17. The display substrate according to claim 1, wherein an orthographic projection of the first conductor portion on the base substrate overlaps with an orthographic projection of the first electrode on the base substrate to form a first overlapping region; and/or
wherein an orthographic projection of the second conductor portion on the base substrate overlaps with an orthographic projection of the second electrode on the base substrate to form a second overlapping region.

18. The display substrate according to claim 17, wherein the first conductor portion is connected to the first electrode through a first via hole, and an orthographic projection of the first via hole on the base substrate is located in the first overlapping region; and/or
wherein the second conductor portion is connected to the second electrode through a second via hole, and an orthographic projection of the second via hole on the base substrate is located in the second overlapping region.

19. The display substrate according to claim 1, wherein the first conductor portion and the second conductor portion comprise a metal oxide or a metal.

20. The display substrate according to claim 1, wherein the electrode layer further comprises at least one fourth electrode and at least one fifth electrode adjacent to each other in the non-display region,
wherein a potential difference between the fourth electrode and the fifth electrode is less than a potential difference between the first electrode and the second electrode, and
wherein a distance between the fourth electrode and the fifth electrode is less than a distance between the first electrode and the second electrode.

21. A display device, comprising the display substrate of claim 1.
